(19) United States
(12) Patent Application Publication
(10) Pub. No.: US 2003/0222803 A1
(43) Pub. Date: Dec. 4, 2003

(54) Duty cycle adapter

(76) Inventors: Shai Cohen, Haifa (IL); Ronnen Lovinger, Ra'anana (IL)

Correspondence Address: WOODCOCK WASHBURN LLP, ONE LIBERTY PLACE, 46TH FLOOR, 1650 MARKET STREET, PHILADELPHIA, PA, 19103, US

(21) Appl. No.: 10/169,332

(22) PCT Filed: Dec. 28, 2000
(86) PCT No.: PCT/IL00/00867

(51) Int. Cl. H03M 5/08; G06F 1/04

(52) U.S. Cl. 341/53

(57) ABSTRACT

A method and apparatus (20) for adjusting a duty cycle of a binary signal (36) having a high phase and a low phase. The method includes applying a delay to the binary signal to create a delayed signal, and performing a Boolean logical operation on the binary signal and the delayed signal, so as to generate an output signal (40, 52) having a duty cycle different from the duty cycle of the binary signal.

### CROSS-REFERENCE TO RELATED APPLICATION

This application claims the benefit of U.S. Provisional Patent Application No. 60/173,226, filed Dec. 28, 1999, entitled “Link sampling adapter,” which is assigned to the assignee of the present patent application and is incorporated herein by reference.

### FIELD OF THE INVENTION

The present invention relates generally to electronic timing circuitry, and specifically to circuitry for controlling the duty cycle of a clock signal.

### BACKGROUND OF THE INVENTION

For systems which transmit pulses, the term “duty cycle” refers to the ratio of the duration of a pulse (pulse width) to the duration between the initiation of successive pulses. Pulses are used for a wide variety of purposes in electronic circuits. An integrated circuit clock, for example, generates a clock signal composed of pulses, to establish a timing signal for use by all of the components on the integrated circuit. These components typically are triggered, as appropriate, by a designated reference point of the clock signal, such as the start of the high phase thereof.

Typically, clock signals used in integrated circuitry are square waves. The duty cycle of a square wave is 0.5 (50%), since the pulses are present half the time. When both the rising and falling edges of the clock signal are used in a circuit, it is particularly critical that the proper duty cycle be maintained, so that the rising-edge and falling-edge transitions are properly spaced. For some purposes, for example, to reconstruct a distorted signal, complex circuits such as phase-locked loops (PLLs) are used to adjust the duty cycle of clock signals or other input signals.

### SUMMARY OF THE INVENTION

It is an object of some aspects of the present invention to provide improved apparatus and methods for adjusting the duty cycle of a signal.

In preferred embodiments of the present invention, a duty cycle adjustment device receives an input signal having high and low phases in a given duty cycle relation, and generates an output signal in which the duty cycle of high and low phases is adjusted, relative to the input signal, substantially without reliance on a phase-locked loop. The device comprises a variable delay unit and a Boolean logic element. The variable delay unit applies a selected delay to the input signal, so as to generate a delayed signal. The input signal and the delayed signal are combined by the Boolean logic element to generate the output signal, whose duty cycle is determined by the selected delay and by the operation of the Boolean logic element. This device thus provides, simple, inexpensive and flexible means for adjusting the duty cycle of a clock or other bi-level signal.

Preferably, the variable delay unit receives the input signal and a modulation signal, which corresponds to an amount by which it is desired to change the duty cycle of the input signal. The variable delay unit generates an output substantially identical to the input signal, but which is delayed with respect thereto by an amount determined by the modulation signal.

In some preferred embodiments of the present invention, a mode selector is set to one of three settings, according to whether (a) the high phase of the input signal is to be lengthened by the delay specified by the modulation signal, thereby increasing the duty cycle, (b) the low phase is to be lengthened, thereby decreasing the duty cycle, or (c) no change is to be applied to the duty cycle of the input signal.

There is therefore provided, in accordance with a preferred embodiment of the present invention, a method for adjusting a duty cycle of a binary signal having a high phase and a low phase, the method including:

applying a delay to the binary signal to create a delayed signal; and

performing a Boolean logical operation on the binary signal and the delayed signal, so as to generate an output signal having a duty cycle different from the duty cycle of the binary signal.

Preferably, the method includes selecting the binary signal as the output signal when no adjustment of the duty cycle is required. Most preferably, performing the Boolean logical operation includes performing the operation substantially without phase-locking to the binary signal.

There is also provided, in accordance with a preferred embodiment of the present invention, apparatus for adjusting a duty cycle of a binary signal having a high phase and a low phase, including:

a delay block, coupled to receive the binary signal and to generate a delayed signal responsive thereto; and

a Boolean logic element, coupled to receive as inputs the binary signal and the delayed signal, and to perform thereon a Boolean logical operation, so as to generate an output signal having a duty cycle different from the duty cycle of the binary signal.

Preferably, the Boolean logic element comprises:

a first Boolean logic element, most preferably an OR gate, coupled to generate a first signal having a duty cycle higher than the duty cycle of the binary signal;

a second Boolean logic element, most preferably an AND gate, coupled to generate a second signal having a duty cycle lower than the duty cycle of the binary signal; and

a selector, coupled to select between the first signal and the second signal.

The present invention will be more fully understood from the following detailed description of the preferred embodiments thereof, taken together with the drawings, in which:

### BRIEF DESCRIPTION OF THE DRAWINGS

FIG. 1 is a block diagram of a circuit for adjusting the duty cycle of a clock signal, in accordance with a preferred embodiment of the present invention;

FIG. 2A is a schematic illustration of a sub-circuit for reducing the duty cycle of the clock signal, in accordance with a preferred embodiment of the present invention;

FIG. 2B is a graph that schematically illustrates signals processed by the sub-circuit of FIG. 2A, in accordance with a preferred embodiment of the present invention;

FIG. 3A is a schematic illustration of a sub-circuit for increasing the duty cycle of the clock signal, in accordance with a preferred embodiment of the present invention; and

FIG. 3B is a graph that schematically illustrates signals processed by the sub-circuit of FIG. 3A, in accordance with a preferred embodiment of the present invention.

### DETAILED DESCRIPTION OF PREFERRED EMBODIMENTS

Reference is now made to FIG. 1, which is a block diagram of a control circuit 20 for adjusting the duty cycle of a clock-in signal 62, in accordance with a preferred embodiment of the present invention. Preferably, circuit 20 comprises an adjustable delay 22, a chop-high sub-circuit 26, for reducing the duration of the high phase of pulses of the clock-in signal, a chop-low sub-circuit 24, for reducing the duration of the low phase of the signal, and an adjustment selector 28. (The chop-high and chop-low sub-circuits are so named because they “chop,” or reduce, the durations of the respective phases of the clock-in signal.)

Adjustable delay 22 preferably receives two inputs: clock-in signal 62 and a set-delay signal 44, which corresponds to an amount by which it is desired to change the duty cycle of clock-in signal 62. Preferably, adjustable delay 22 generates an output, delay-in signal 66, which is substantially identical to clock-in signal 62, but which is delayed with respect thereto by an amount determined by set-delay signal 44. Typically, adjustable delay 22 can be continuously varied by set-delay signal 44 to apply delays to clock-in signal 62 which range from zero to 100% of a clock cycle. Alternatively, settings are in discrete increments, such as 10%, 20%, 30% and 40%. Adjustable delay 22 preferably utilizes delay-generating apparatus described in a PCT patent application entitled “Variable delay generator,” filed on even date, which is assigned to the assignee of the present patent application and is incorporated herein by reference.

Preferably, sub-circuits 24 and 26 process delay-in signal 66 in combination with clock-in signal 62, in order to generate a new clock signal having a different duty cycle from that of clock-in signal 62. Specifically, chop-high sub-circuit 26 produces a chop-high signal 70, with a lower duty cycle than that of clock-in signal 62, and chop-low sub-circuit 24 produces a chop-low signal 68, with a higher duty cycle than that of clock-in signal 62.

Adjustment selector 28 is preferably configured to output a clock-out signal 64, which comprises the output of control circuit 20. Typically, selector 28 is set to one of three settings, according to whether (a) the high phase of clock-in signal 62 is to be lengthened by the delay specified by set-delay signal 44, thereby increasing the duty cycle, (b) the low phase is to be lengthened, thereby decreasing the duty cycle, or (c) no change is to be applied to the duty cycle of clock-in signal 62. These three settings correspond respectively to the three inputs to selector 28 shown in FIG. 1: chop-low signal 68, chop-high signal 70, and a third, “no-change” input, which is directly connected to clock-in signal 62.

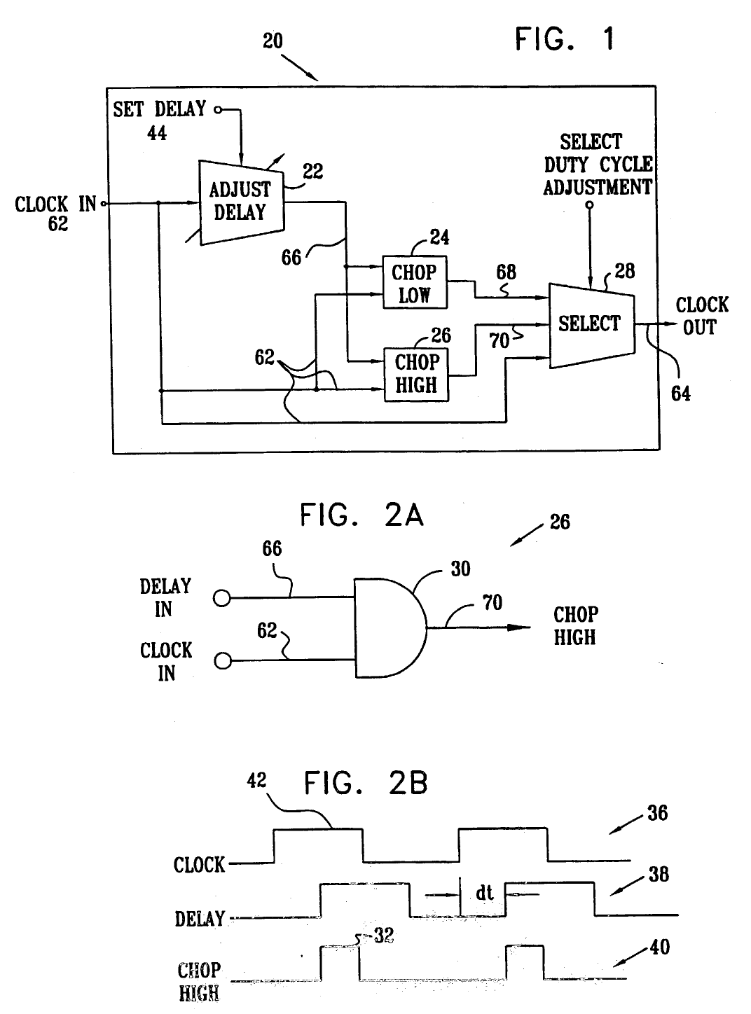

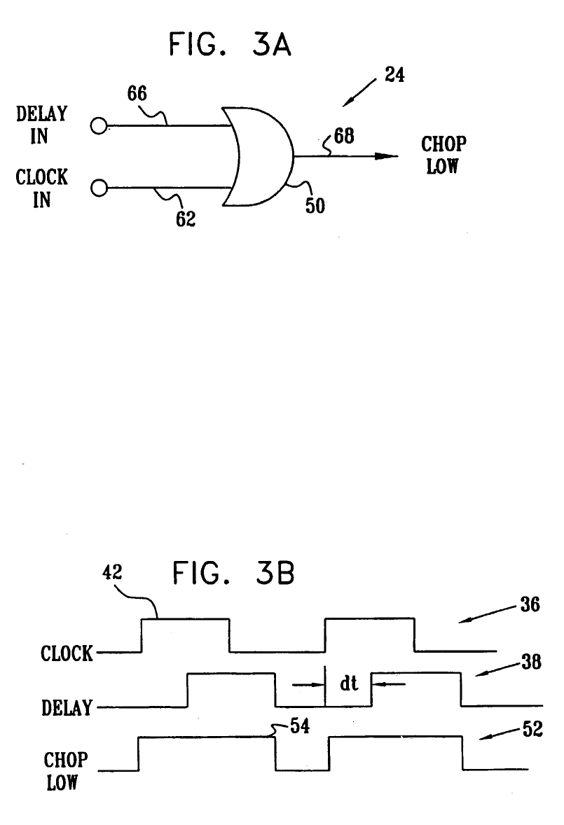

FIG. 2A is a schematic illustration showing details of sub-circuit 26, in accordance with a preferred embodiment of the present invention. Preferably, chop-high sub-circuit 26 comprises an “AND” gate 30, whose inputs are clock-in signal 62 and delay-in signal 66. Clock-in signal 62 and delay-in signal 66 have Boolean values, i.e., their values can either be one (high phase) or zero (low phase). Responsive to these inputs, AND gate 30 generates chop-high signal 70, which is conveyed to adjustment selector 28 (FIG. 1). If selector 28 is set to select the chop-high signal, then signal 70 (essentially clock-in signal 62 with a reduced duty cycle) exits circuit 20 as clock-out 64.

FIG. 2B is a graph that schematically illustrates a sample clock-in signal 36, a delay-in signal 38, generated by adjustable delay 22 from clock-in signal 36, and a chop-high signal 40, generated by AND gate 30 based on signals 36 and 38, in accordance with a preferred embodiment of the present invention. A high phase 32 of chop-high signal 40 is seen to match a high phase 42 of clock-in signal 36, but only to the extent that clock-in signal 36 and delay-in signal 38 are mutually in phase. As signals 36 and 38 go out of phase (e.g., the approximately 50% phase lag shown in FIG. 2B), the time during which chop-high signal 40 is in the high phase thereof is concomitantly decreased by the amount of the delay (dt) between the rising phases of the clock-in and delay-in signals. In this manner, sub-circuit 26 reduces the duty cycle of the clock-in signal. Although clock-in signal 36 is shown in FIG. 2B as a square wave by way of example, other signal forms can be used.

FIG. 3A is a schematic illustration showing details of sub-circuit 24, in accordance with a preferred embodiment of the present invention. Preferably, chop-low sub-circuit 24 comprises an “OR” gate 50, which receives as inputs clock-in signal 62 and delay-in signal 66. Using these inputs, OR gate 50 generates chop-low signal 68. It is noted that these embodiments of the present invention show the AND gate and the OR gate as examples of apparatus for implementing the chop-high and chop-low sub-circuits. In other preferred embodiments, however, other circuitry configurations may be used, and are considered to be within the scope of the present invention.

FIG. 3B is a graph that schematically illustrates sample clock-in signal 36, delay-in signal 38, and a chop-low signal 52 generated by OR gate 50, responsive to signals 36 and 38, in accordance with a preferred embodiment of the present invention. A high phase 54 of chop-low signal 52 is seen to coincide with high phase 42 of clock-in signal 36, and, additionally, to coincide with the high phase of delay-in signal 38. Thus, as signals 36 and 38 go out of phase, the time during which chop-low signal 52 is in the high phase thereof is increased by the amount of the delay (dt) between the rising phases of the clock-in and delay-in signals. Because the duration of the high phase is increased by dt, the duty cycle of clock-in signal 36 is increased. Thus, setting selector 28 to output the chop-low signal will make the output of control circuit 20 be a signal having the same frequency as the clock-in signal, but having a duty cycle increased by a desired amount.

It will be appreciated that the preferred embodiments described above are cited by way of example, and that the present invention is not limited to what has been particularly shown and described hereinabove. Rather, the scope of the present invention includes both combinations and sub-combinations of the various features described hereinabove, as well as variations and modifications thereof which would occur to persons skilled in the art upon reading the foregoing description, and which are not disclosed in the prior art.

1. A method for adjusting a duty cycle of a binary signal having a high phase and a low phase, the method comprising:
applying a delay to the binary signal to create a delayed signal; and
performing a Boolean logical operation on the binary signal and the delayed signal, so as to generate an output signal having a duty cycle different from the duty cycle of the binary signal.

2. A method according to claim 1, wherein performing the Boolean logical operation comprises:
performing a first Boolean logical operation on the binary signal and the delayed signal, so as to generate a first signal having a duty cycle higher than the duty cycle of the binary signal;
performing a second Boolean logical operation on the binary signal and the delayed signal, so as to generate a second signal having a duty cycle lower than the duty cycle of the binary signal; and
selecting between the first and second signals, so as to generate the output signal.

3. A method according to claim 2, and comprising selecting the binary signal as the output signal when no adjustment of the duty cycle is required.

4. A method according to any of claims 1-3, wherein performing the Boolean logical operation comprises performing the operation substantially without phase-locking to the binary signal.

5. Apparatus for adjusting a duty cycle of a binary signal having a high phase and a low phase, comprising:
a delay block, coupled to receive the binary signal and to generate a delayed signal responsive thereto; and
a Boolean logic element, coupled to receive as inputs the binary signal and the delayed signal, and to perform thereon a Boolean logical operation, so as to generate an output signal having a duty cycle different from the duty cycle of the binary signal.

6. Apparatus according to claim 5, wherein the Boolean logic element comprises:
a first Boolean logic element, coupled to generate a first signal having a duty cycle higher than the duty cycle of the binary signal;
a second Boolean logic element, coupled to generate a second signal having a duty cycle lower than the duty cycle of the binary signal; and
a selector, coupled to select between the first signal and the second signal.

7. Apparatus according to claim 6, wherein the second Boolean logic element comprises an AND gate.

8. Apparatus according to claim 7, wherein the first Boolean logic element comprises an OR gate.

9. Apparatus according to any of claims 6-8, wherein the selector is further coupled to select the binary signal as the output signal when no adjustment of the duty cycle is required.
